(19) United States
(12) Patent Application Publication
(10) Pub. No.: US 2012/0206157 A1
(43) Pub. Date: Aug. 16, 2012

(54) Structure of burn-in oven

(75) Inventor: Yen-Chang Liu, Hsinchu (TW)

(73) Assignee: King Yuan Electronics Co., Ltd., Hsinchu (TW)

(21) Appl. No.: 13/137,802

(22) Filed: Sep. 14, 2011

(30) Foreign Application Priority Data
Feb. 10, 2011 (TW) 100202555

(51) Int. Cl. G01R 31/10

(52) U.S. Cl. 324/750.05

(57) ABSTRACT

An improved structure of a burn-in oven includes a housing, a loading support, a cooling-fan assembly, and a motor-fan assembly. A circuit-board-space and an exhaust channel are defined inside of the housing, wherein the exhaust channel is provided with a plurality of venting holes such that the circuit-board-space and the exhaust channel are communicated with each other through the venting holes. The loading support is disposed in the circuit-board-space for loading a plurality of circuit boards. The cooling-fan assembly is arranged at one side of the loading support and beside the exhaust channel. The motor-fan assembly is arranged at the exhaust channel. Thereby, a phenomenon of heat accumulation locally at a back panel side of the oven can be improved so as to enhance cooling effect of the oven, let alone the number of fans installed on the oven can be decreased.

### BACKGROUND OF THE INVENTION

1. Field of the Invention

The present invention relates to a burn-in oven, and more particularly, to an improved structure of a burn-in oven for enhancing cooling effect on a back panel side of the oven.

2. Description of Related Art

Certain electronic components or chip packages, such as integrated circuits (ICs), are quite often installed, in a form of compact-size electronic components, in circuits consisting of electronic components, so that a continuous complete circuit can be established. To assure reliability of IC modules during use thereof, the IC modules have to be undertaken a burn-in test prior to being installed or used. In other words, to proceed with a high-temperature operation to the IC modules for a long time will make defective IC modules failed as soon as possible so as to screen and eliminate the defective IC modules. This process is referred to as a “burn-in test.”

Referring to FIG. 1, a schematic view illustrating a conventional back panel side of a burn-in oven, the burn-in oven comprises primarily a housing 90 consisting of an insertion-slot side 901 and a back panel side 902 arranged opposite to each other. Inside the housing 90 there are defined with a to-be-tested-components-space 98 and a circuit-board-space 91 located respectively at the insertion-slot side 901 and the back panel side 902. Namely, the to-be-tested-components-space 98 is provided for receiving components for proceeding with burn-in tests, and the circuit-board-space 91 for receiving burn-in related circuit boards 92.

As shown in FIG. 1, the circuit boards 92 are received in such a manner that there are two loading supports 93 provided in the circuit-board-space 91, where a plurality of circuit boards 92 are arrayed vertically along the housing 90 and are loaded on the loading supports 93, respectively. Since during operation of the burn-in oven the circuit boards 92 will produce waste heat, a design for cooling purpose thereof is a must. As shown, there are two motor-fan assemblies 94 (each including a motor and a fan) provided above the circuit-board-space 91, attempting to pump cooling air from a cooler-air source (such as air of an outside environment) into the circuit-board-space 91; while a plurality of cooling-fan assemblies 96 of relatively low power are arranged beside the loading supports 93. A venting chamber 95 is provided at a lateral side of the housing 90 for communicating directly with the circuit-board-space 91.

Cooling air flows from above of the circuit-board-space 91, guided by the cooling-fan assemblies 96 and flowing through the circuit boards 92, and enters into the venting chamber 95. The venting chamber 95 serves as a route for exhausting air of higher temperature exiting from the housing 90. However, to assure exhausting the air along the venting chamber 95, blowers 97 are additionally arranged beside the motor-fan assemblies 94.

According to the conventional burn-in oven, heat will be accumulated at a lower portion of the back panel side. This will adversely affect function of the circuit boards. As such, the conventional art is undesirable.

### SUMMARY OF THE INVENTION

A primary object of the present invention is to provide an improved structure of a burn-in oven for improving a phenomenon of heat accumulation at the lower portion of a back panel side of the oven so as to assure a stable operation of facilities.

To achieve the object, the improved structure of a burn-in oven comprises a housing, a loading support, a cooling-fan assembly, and a motor-fan assembly. A circuit-board-space and an exhaust channel are defined inside the housing, wherein the exhaust channel is provided with a plurality of venting holes such that the circuit-board-space and the exhaust channel are communicated with each other through the plural venting holes.

Further, according to the present invention, the loading support is disposed in the circuit-board-space for loading a plurality of circuit boards. The cooling fan assembly is arranged at one side of the loading support and beside the exhaust channel, and that the motor-fan assembly is arranged at the exhaust channel.

Through the structure, as designed above, a cooling-air flow on the back panel side of the oven can flow through the circuit boards more uniformly at various locations so as to improve heat accumulation at the lower portion of the back panel side of the oven. Besides, according to the present invention, even though less number of fan devices are used, a more predominant cooling effect over the conventional art can be achieved. As such, the present invention has a merit on energy saving.

According to the present invention, a venting chamber may be further defined inside of the housing for communicating with the circuit-board-space. The exhaust channel relates to a pipe arranged in the venting chamber. In other words, by making a bit of modification on the conventional burn-in oven, an improved structure of the burn-in oven, according to the present invention, can be reached.

According to the present invention, the motor-fan assembly may be arranged at any appropriate place, for instance at an end of the exhaust channel. At least one of the plural venting holes is arranged with a gate, so that communication between the exhaust channel and the circuit-board-space can be controlled. In such a way, the exhaust channel can fit various housing systems, and by opening or closing a specific gate, an optimal cooling effect can be obtained.

Further, according to the present invention, even not to consider making modification on the conventional structure of a burn-in oven, designing the exhaust channel as part of the housing is an alternate. Namely, by replacing a communicating interface of quite large area between the conventional circuit-board-space and venting chamber with a wall, and providing a plurality of venting holes on the wall, an enhanced cooling effect can be obtained, and as such, the phenomenon of heat accumulation at certain part of the oven can be improved. Of course, such design can also accompany with at least one of the venting holes arranged with a gate.

Other objects, advantages, and novel features of the present invention will become more apparent from the following detailed descriptions when taken in conjunction with the accompanying drawings.

### BRIEF DESCRIPTION OF THE DRAWINGS

FIG. 1 is a schematic view illustrating a conventional back panel side of a burn-in oven;

FIG. 2 is a schematic view illustrating a back panel side of a burn-in oven according to a first embodiment of the present invention;

FIG. 3A is a cross-sectional view illustrating an exhaust channel of a burn-in oven according to a second embodiment of the present invention, when an exhaust channel gate is opened;

FIG. 3B is a cross-sectional view illustrating the exhaust channel of a burn-in oven according to the second embodiment of the present invention, when the exhaust channel gate is closed;

FIG. 4 is a schematic view illustrating a back panel side of a burn-in oven according to a third embodiment of the present invention; and

FIG. 5 is a front view illustrating a back panel side of a burn-in oven according to a fourth embodiment of the present invention.

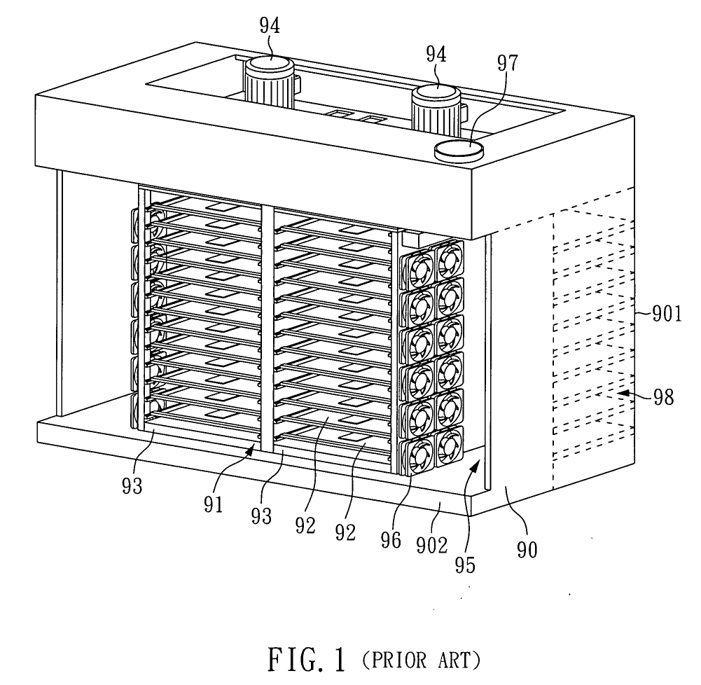

### DETAILED DESCRIPTION OF THE PREFERRED EMBODIMENTS

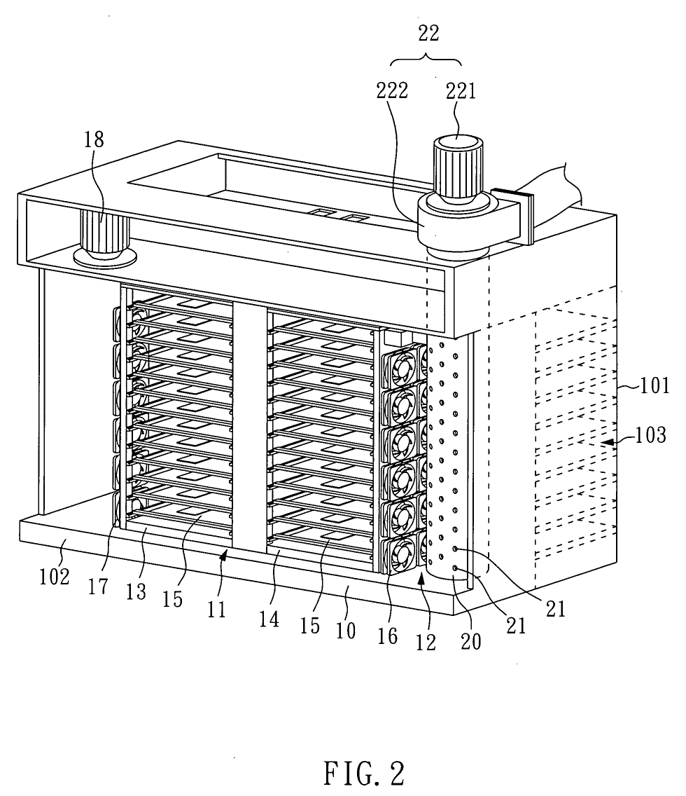

Reference is made to FIG. 2, a schematic view illustrating a back panel side of a burn-in oven according to a first embodiment of the present invention, where a back cover plate has been removed so as to reveal clearly inside of the oven, in the present embodiment, as a modification made on a conventional oven housing, the burn-in oven comprises a housing 10 consisting of an insertion-slot side 101 and a back panel side 102 arranged opposite to each other. A to-be-tested-components-space 103 is defined inside of the housing 10 at the insertion-slot side 101; whereas a circuit-board-space 11 and a venting chamber 12, as shown in FIG. 2, are defined inside of the housing 10 at the back panel side 102, wherein the venting chamber 12 and the circuit-board-space 11 are communicated with each other directly. A pipe-like exhaust channel 20 is vertically arranged in the venting chamber 12, with its end extending outside of the housing 10, in particular, with a plurality of venting holes 21 provided around the exhaust channel 20.

Further, as shown in FIG. 2, two loading supports 13,14 are disposed in the circuit-board-space 11, where a plurality of circuit boards 15 are loaded on the loading supports 13,14 and are arrayed vertically along the housing 10, constituting plural circuit-board arrays. There are cooling-fan assemblies 16,17 arranged at one side of the loading supports 13,14, respectively. The cooling-fan assemblies 16,17 each includes a plurality of fans located corresponding to the plural circuit-board arrays. Among them, the cooling-fan assembly 16 for the loading support 14 is located beside the exhaust channel 20.

There is also a motor-fan assembly 22 arranged at the exhaust channel 20. In the present embodiment, the motor-fan assembly 22 is arranged at an end of the exhaust channel 20. The motor-fan assembly 22 refers to an assembly of a motor 221 and a driven fan 222. The fan 222 is arranged, coaxially, on a spindle of the motor 221.

For a practical operation, cooling air is pumped into the circuit-board-space 11 by single motor-fan assembly 18 located above the circuit-board-space 11. Then the cooling-fan assemblies 16,17 force the cooling air to flow through the plural circuit boards 15. At this moment, since the exhaust channel 20 and the circuit-board-space 11 are communicated with each other only through the venting holes 21, and since the motor-fan assembly 22 which is more powerful in blowing air is arranged at the exhaust channel 20, the exhaust channel 20 turns into a comparatively vacuumed environment. As a result, the cooling air tends to flow toward the venting holes 21, and has a more uniform distribution of flow for the circuit boards 15 at various locations. This means that those circuit boards 15, even located at a lower portion of the circuit-board-space 11, can still receive more cooling-air flow than that by the conventional art.

As revealed from practical experiments, the burn-in oven, according to the present invention, improves the phenomenon of heat accumulation at the lower portion of the oven housing for about a temperature difference up to 25° C.

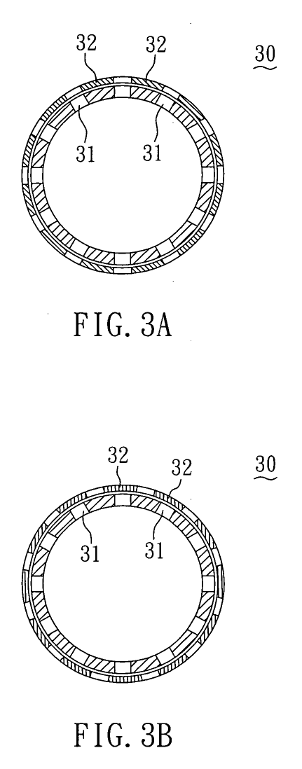

Now referring to FIG. 3A, a cross-sectional view illustrating an exhaust channel of a burn-in oven according to a second embodiment of the present invention, when an exhaust channel gate is opened, and to FIG. 3B, a cross-sectional view illustrating the exhaust channel of a burn-in oven according the second embodiment of the present invention, when the exhaust channel gate is closed, the present embodiment is, in terms of structure, substantially similar to the first embodiment, except that venting holes 31 of an exhaust channel 30 can be opened or closed selectively. For example, by arranging a gate 32, communication between the exhaust channel 30 and a circuit-board-space can be controlled. Through such a design for selectively opening or closing the venting holes, an enhanced cooling effect can be obtained for a lower portion of the oven housing when the venting holes 31 at an upper portion of the exhaust channel 30 are closed. Therefore, to install the pipe-like exhaust channel 30, according to the present embodiment, to various oven-housing systems, an optimal cooling effect can be obtained with an adaptation adjustment.

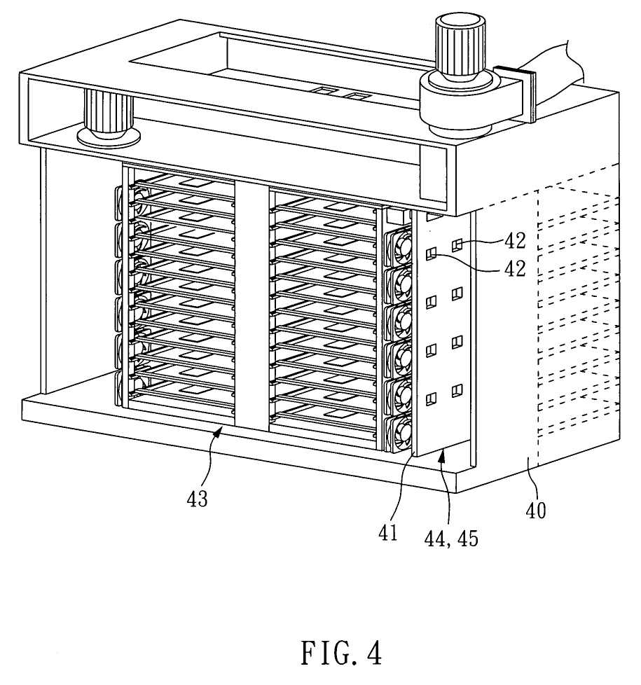

Further referring to FIG. 4, a schematic view illustrating a back panel side of a burn-in oven according to a third embodiment of the present invention, where a back cover plate has been removed so as to reveal clearly inside of the oven, in the present embodiment, the structure of a burn-in oven is characterized in that an exhaust channel 45 is formed in the following way: a wall 41 is provided to replace a communicating interface of large area between the conventional circuit-board-space and venting chamber, and a plurality of venting holes 42 are provided on the wall 41, so that communication between a circuit-board-space 43 and a venting chamber 44 (acting as the exhaust channel 45) can be achieved through the plural venting holes 42. Of course, the wall 41 may be mounted, additionally, on the conventional burn-in oven; or may be integrally made with an oven housing 40 such that the wall 41 becomes a part of the housing 40. The present embodiment also improves heat accumulation at a lower portion of the housing 40.

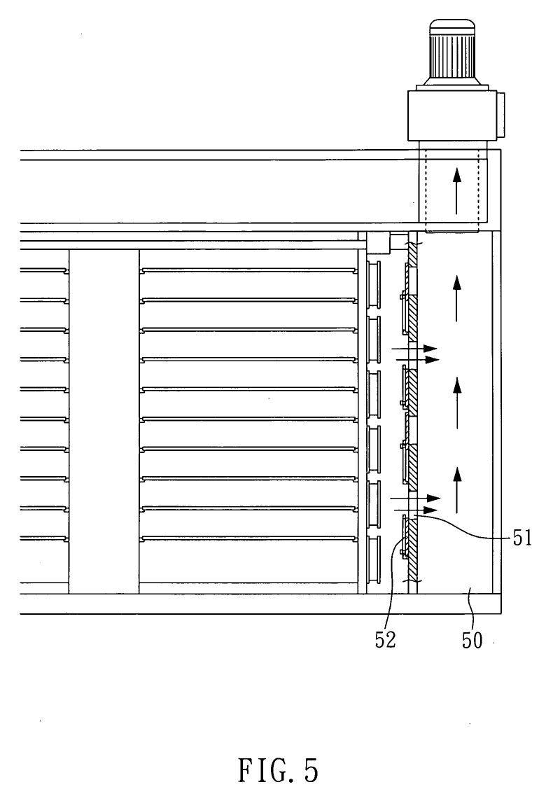

Referring to FIG. 5, a front view illustrating a back panel side of a burn-in oven according to a fourth embodiment of the present invention, the present embodiment is substantially similar, in terms of structure, to the third embodiment, except that venting holes 51 of an exhaust channel 50 can be opened or closed selectively, for instance, a measure taken as gates 52 and similar to those shown in FIG. 3.

In view of the above, it is understood that the present invention, though uses the same or less number of motor-fan assembles, can obtain a more desirable cooling effect. For example, the embodiment of the present invention shown in FIG. 2, though does not use the blowers 97 as the conventional art, can greatly increase cooling effect and thus improve the problem of heat accumulation at the lower portion of the oven housing. According to the present invention, since lesser number of fan devices are used, not only cost on purchase and maintenance can be saved, but also power demand for the fan devices is naturally lowered. As such, the purposes of energy saving and environmental protection can be reached.

Although the present invention has been explained in relation to its preferred embodiments, it is to be understood that many other possible modifications and variations can be made without departing from the scope of the invention as hereinafter claimed.

What is claimed is:

1. An improved structure of a burn-in oven, comprising:
a housing, being defined inside of the housing with a circuit-board-space and an exhaust channel, wherein the exhaust channel is provided with a plurality of venting holes such that the circuit-board-space and the exhaust channel are communicated with each other through the plural venting holes;
a loading support, being disposed in the circuit-board-space for loading a plurality of circuit boards;
a cooling-fan assembly, being arranged at one side of the loading support and beside the exhaust channel; and
a motor-fan assembly, being arranged at the exhaust channel.

2. The improved structure of a burn-in oven as claimed in claim 1, wherein a venting chamber is further defined inside of the housing for communicating with the circuit-board-space, and the exhaust channel relates to a pipe arranged in the venting chamber.

3. The improved structure of a burn-in oven as claimed in claim 2, wherein the motor-fan assembly is arranged at an end of the pipe.

4. The improved structure of a burn-in oven as claimed in claim 2, wherein at least one of the plural venting holes is arranged with a gate.

5. The improved structure of a burn-in oven as claimed in claim 1, wherein the exhaust channel is part of the housing.

6. The improved structure of a burn-in oven as claimed in claim 5, wherein at least one of the venting holes is arranged with a gate.
